(19) United States
(12) Patent Application Publication
(10) Pub. No.: US 2017/0045473 A1
(43) Pub. Date: Feb. 16, 2017

(54) GAS SENSOR AND METHOD OF MANUFACTURING THE SAME

(71) Applicant: ELECTRONICS AND TELECOMMUNICATIONS RESEARCH INSTITUTE, Daejeon (KR)

(72) Inventors: Young-Jun YU, Daejeon (KR); Hong Kyw CHOI, Busan (KR); Choon Gi CHOI, Daejeon (KR); Jin Tae KIM, Daejeon (KR); Young Kyu CHOI, Daejeon (KR); Jin Sik CHOI, Daejeon (KR)

(73) Assignee: ELECTRONICS AND TELECOMMUNICATIONS RESEARCH INSTITUTE, Daejeon (KR)

(21) Appl. No.: 15/190,651

(22) Filed: Jun. 23, 2016

(30) Foreign Application Priority Data
Aug. 11, 2015 (KR) 10-2015-0113190
Mar. 11, 2016 (KR) 10-2016-0029510

(51) Int. Cl. G01N 27/414; H01L 21/02; H01L 29/45; H01L 29/16; H01L 29/24

(52) U.S. Cl. CPC G01N 27/4141; H01L 29/1606; H01L 29/24; H01L 29/45; H01L 21/02527; H01L 21/02568; H01L 21/02521; H01L 21/0262

(57) ABSTRACT

Provided herein is a gas sensor that includes a substrate, an insulating layer provided on the substrate, a first active layer disposed on the insulating layer, a second active layer which is disposed on the insulating layer and undergoes heterojunction with a portion of the first active layer, a first electrode and a second electrode which are disposed on the first active layer and are spaced apart from each other at a predetermined interval, and a third electrode and a fourth electrode which are disposed on the second active layer and are spaced apart from each other at a predetermined interval. The first active layer and the second active layer include different materials.

### CROSS-REFERENCE TO RELATED APPLICATION

The present application claims priority to Korean Patent Application Numbers 10-2015-0113190 filed on Aug. 11, 2015 and 10-2016-0029510 filed on Mar. 11, 2016, in the Korean Intellectual Property Office, the entire disclosure of which is incorporated by reference herein.

### BACKGROUND

Field of Invention

Various embodiments of the present disclosure relate to a gas sensor and a method of manufacturing the same.

Description of Related Art

Technologies for detecting harmful materials in the air in real time are very important. It is virtually impossible to quantify the concentration of dangerous gases or judge the type of the gases using human sensory organs. Accordingly, a gas sensor using physical and chemical properties of materials has been developed for use in sensing a gas leak, measuring and recording the concentration, and warning. The gas sensor may be broadly classified into a catalytic combustion type and a semiconductor type.

The catalytic combustion gas sensor measures a change in electric resistance to detect gases. The catalytic combustion gas sensor is insignificantly influenced by steam, the temperature, and moisture, but has a drawback in that oxygen should be present in a sufficient amount due to difficulty in perfectly oxidizing gases at low temperatures and a low reaction speed.

The semiconductor gas sensor uses a reduction in electric resistance when gases come into contact with semiconductors. The semiconductor gas sensor is advantageous in that the number of sensed gases is large, it is easy to manufacture the sensor, and a detection circuit has a simple constitution. However, there are drawbacks in that a high-temperature condition should be ensured during measurement to increase the size of the sensor, entail an initial delay phenomenon, and allow the sensor to be significantly influenced by the ambient temperature and moisture.

There is a need to overcome the drawbacks of the gas sensors and make research into manufacturing a high-sensitive sensor.

### SUMMARY

Various embodiments of the present disclosure are directed to a gas sensor which includes a heterojunction channel layer of a 2-dimensional material to ensure stable and high reaction sensitivity.

Furthermore, various embodiments of the present disclosure are directed to a method of manufacturing the gas sensor.

One embodiment of the present disclosure provides a gas sensor that includes a substrate, an insulating layer disposed on the substrate, a first active layer disposed on the insulating layer, a second active layer which is disposed on the insulating layer and undergoes heterojunction with a portion of the first active layer, a first electrode and a second electrode which are disposed on the first active layer and are spaced apart from each other at a predetermined interval, and a third electrode and a fourth electrode which are disposed on the second active layer and are spaced apart from each other at a predetermined interval. The first active layer and the second active layer may include different materials.

In the embodiment of the present disclosure, the first active layer may include a black phosphorus material.

In the embodiment of the present disclosure, the second active layer may include a graphene material.

In the embodiment of the present disclosure, the second active layer may include a transition metal dichalcogenide material.

In the embodiment of the present disclosure, the first active layer and the second active layer may be positioned on the same line on the basis of a planar view.

In the embodiment of the present disclosure, the first electrode and the second electrode may be in contact with the first active layer and may sense a change in current of the first active layer.

In the embodiment of the present disclosure, the third electrode and the fourth electrode may be in contact with the second active layer and may sense a change in current of the second active layer.

In the embodiment of the present disclosure, the second electrode and the third electrode may be spaced apart from a junction unit, at which the first active layer and the second active layer are in contact with each other, by a predetermined distance, and may sense a change in current of the junction unit.

In the embodiment of the present disclosure, the first to fourth electrodes may include any one selected from the group consisting of gold (Au), aluminum (Al), silver (Ag), beryllium (Be), bismuth (Bi), cobalt (Co), copper (Cu), chromium (Cr), hafnium (Hf), indium (In), manganese (Mn), molybdenum (Mo), magnesium (Mg), nickel (Ni), niobium (Nb), lead (Pb), palladium (Pd), platinum (Pt), rhodium (Rh), rhenium (Re), ruthenium (Ru), antimony (Sb), tantalum (Ta), tellurium (Te), titanium (Ti), vanadium (V), tungsten (W), zirconium (Zr), zinc (Zn), and combinations thereof.

Another embodiment of the present disclosure provides a method of manufacturing a gas sensor, the method including forming an insulating layer on a substrate, forming a first active layer on the insulating layer, forming a second active layer, which undergoes heterojunction with a portion of the first active layer, on the insulating layer, and forming a first electrode and a second electrode, which are spaced apart from each other at a predetermined interval, on the first active layer, and forming a third electrode and a fourth electrode, which are spaced apart from each other at a predetermined interval, on the second active layer. The first active layer and the second active layer may include different materials.

The present disclosure provides a gas sensor which includes first and second active layers including different materials to improve reaction sensitivity.

The present disclosure also provides a gas sensor ensuring the high measurement performance over a long period of time even in the air.

The present disclosure also provides a method of easily manufacturing the gas sensor.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a perspective view showing a gas sensor according to an embodiment of the present disclosure;

FIG. 2 is a sectional view taken along the line I-I′ of FIG. 1;

FIGS. 3 to 6 are sectional views sequentially showing manufacturing of the gas sensor of FIG. 2; and

FIG. 7 is a sectional view of a gas sensor according to another embodiment of the present disclosure.

### DETAILED DESCRIPTION

Specific structural or functional descriptions in the embodiments of the present invention disclosed in the specification or application are only for description of the embodiments of the present invention. The descriptions can be embodied in various forms and should not be construed as being limited to the embodiments described in the specification or application.

Given the fact that various modifications of the present disclosure are possible, embodiments of the present disclosure will be explained in this specification. However, these embodiments are not intended to limit the present disclosure to special forms. Rather, all changes that fall within the bounds of the present disclosure, or the equivalence of the bounds should be understood to be embraced by the present disclosure.

In the drawings, like reference numerals refer to like elements throughout. Sizes of elements in the drawings may be exaggerated for clarity of illustration. Also, although terms like “first” and “second” are used to describe various components, the components are not limited to these terms. Such terms are used only to differentiate one component from another one. For example, a component referred to as a first component in an embodiment may be referred to as a second component in another embodiment. In a similar manner, a second component may be referred to as a first component. The terms in a singular form may include plural forms unless otherwise specified.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, when an element such as a layer, film, region, or substrate is referred to as being “on” another element, it can be directly on the other element or intervening elements may also be present. Alternatively, when an element such as a layer, film, region, or substrate is referred to as being “under” another element, it may be directly under the other element or intervening elements may also be present.

Hereinafter, embodiments of the present disclosure will be described in detail with reference to the attached drawings.

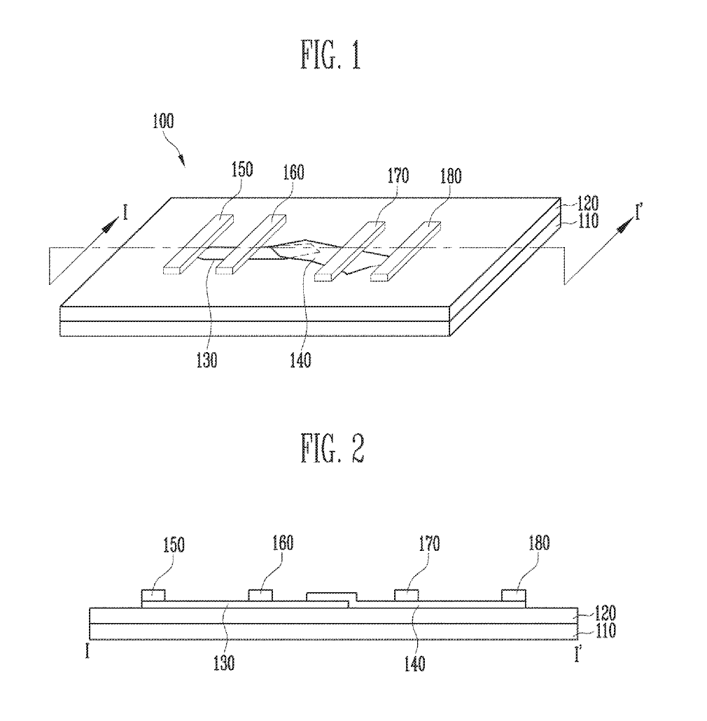

FIG. 1 is a perspective view showing a gas sensor according to an embodiment of the present disclosure, and FIG. 2 is a sectional view taken along the line I-I′ of FIG. 1.

Referring to FIGS. 1 and 2, a gas sensor 100 according to the embodiment of the present disclosure may include a substrate 110, an insulating layer 120, a first active layer 130, a second active layer 140, a first electrode 150, a second electrode 160, a third electrode 170, and a fourth electrode 180.

The substrate 110 is a base board used as a semiconductor element. Examples of the base board may include a transparent inorganic base board, which includes glass, quartz, AlO, SiC, or MgO, a transparent flexible organic base board, which includes polyethylene terephthalate (PET), polystyrene (PS), polyimide (PI), polyvinyl chloride (PVC), polyvinylpyrrolidone (PVP), or polyethylene (PE), or a base board, which includes Si, Ge, GaAs, InP, InSb, InAs, AlAs, AlSb, CdTe, ZnTe, ZnS, CdSe, CdSb, or GaP, but are not limited thereto.

In the embodiment of the present disclosure, the substrate 110 may include silicon, glass, or quartz, without being limited thereto.

The insulating layer 120 may be provided on the substrate 110 and may include a monolayer or a multilayer. The insulating layer 120 may include a material, such as silicon nitrides (SiNx), silicon oxides (SiO2), BCB (benzocyclobutene), and other porous silica thin films, and may function to protect the surface of the substrate 110. The type and the thickness of the insulating layer 120 may determined in consideration of etch rates of photosensitive layers used during a process.

The first active layer 130 may be disposed on the insulating layer 120 and may undergo heterojunction with a portion of the second active layer 140. The first active layer 130 may include a layer in which a black phosphorus material having a 2-dimensional combination structure of black phosphorus (P) is deposited in a thin film form. The first active layer 130 may be formed on the insulating layer 120 so as to have a predetermined area, an atomic layer thickness, and a width of ones μm. The first active layer 130 may be used as a current path between the first electrode 150 and the second electrode 160, that is, a first channel region.

The black phosphorus material may be obtained from ore, which is collected from nature, or using a synthesis process in a high temperature and high pressure environment. The black phosphorus material has the high mobility and band gap, and the state of the black phosphorus material is rapidly converted between insulation and conduction states.

The second active layer 140 may be disposed on the insulating layer 120 and may undergo heterojunction with the first active layer 130 at a portion thereof. The second active layer 140 may include a graphene material having a 2-dimensional planar combination structure, without being limited thereto. The second active layer 140 may include a transition metal dichalcogenide material having a 2-dimensional combination structure in addition to the graphene material. Hereinafter, a description will be given of the second active layer 140 including the graphene material.

The second active layer 140 may be formed on the insulating layer 120 so as to have a predetermined area, an atomic layer thickness, and a width of ones nm. The second active layer 140 may include a monolayer, a double layer, or a multilayer, and may directly grow on the insulating layer 120, without being limited thereto. The second active layer 140 may be used as a current path between the third electrode 170 and the fourth electrode 180, that is, a second channel region.

The graphene material, which is formed on another base board, may be transferred on the insulating layer 120 to thus form the second active layer, without being limited thereto. For example, the transferred flake sample or the reduced graphene oxides may be used as the second active layer 140, without being limited thereto. The graphene material has high thermal conductivity, excellent mobility of charge carriers, a large specific surface area, and excellent mechanical stability.

A junction unit, at which the first active layer 130 undergoes heterojunction with the second active layer 140, may be used as a current path between the second electrode 160 and the third electrode 170, that is, a third channel region.

The first active layer 130 and the second active layer 140 may be disposed on the same line on the insulating layer 120 on the basis of a planar view. The first active layer 130 and the second active layer 140 may serve as the gas sensing layer of the gas sensor 100 due to properties of the materials (black phosphorus and graphene) constituting the layers.

The black phosphorus material and the graphene material, which constitute the first active layer 130 and the second active layer 140, respectively, may have the uniformity of a uniform monoatomic structure having a 2-dimensional shape and small thermal noise to thus ensure high sensitivity and be easily shaped into various forms.

The first electrode 150 and the second electrode 160 may be disposed on the first active layer 130 and spaced apart from each other at a predetermined interval. The first electrode 150 and the second electrode 160 may include any metal materials having the conductivity to allow a current to flow through the first active layer 130. For example, the first electrode 150 and the second electrode 160 may include any one selected from the group consisting of gold (Au), aluminum (Al), silver (Ag), beryllium (Be), bismuth (Bi), cobalt (Co), copper (Cu), chromium (Cr), hafnium (Hf), indium (In), manganese (Mn), molybdenum (Mo), magnesium (Mg), nickel (Ni), niobium (Nb), lead (Pb), palladium (Pd), platinum (Pt), rhodium (Rh), rhenium (Re), ruthenium (Ru), antimony (Sb), tantalum (Ta), tellurium (Te), titanium (Ti), vanadium (V), tungsten (W), zirconium (Zr), zinc (Zn), and combinations thereof, but are not limited thereto. A change in current of the first active layer 130 may be sensed using the first electrode 150 and the second electrode 160.

The third electrode 170 and the fourth electrode 180 may be disposed on the second active layer 140 and spaced apart from each other at a predetermined interval. The third electrode 170 and the fourth electrode 180 may include the same materials as the first and second electrodes 150 and 160. A change in current of the second active layer 140 may be sensed using the third electrode 170 and the fourth electrode 180.

The second electrode 160 and the third electrode 170 may be spaced apart from the junction unit, at which the first active layer 130 undergoes heterojunction with the second active layer 140, by a predetermined distance. A change in current of the junction unit may be sensed using the second electrode 160 and the third electrode 170.

Meanwhile, the gas sensor 100 according to the embodiment of the present disclosure may be provided in a chamber (not shown) which is configured on a printed circuit board (not shown) to be essentially maintained in a vacuum. A change in properties of the first active layer 130 and the second active layer 140 may be measured using the gas sensor 100 to sense a gas leak in the chamber.

The gas sensor 100 includes the first active layer 130 including the black phosphorus material, and the second active layer 140 including the graphene material. Further, the gas sensor 100 further includes the junction unit, at which the first active layer 130 partially undergoes heterojunction with the second active layer 140.

When the black phosphorus material and the graphene material come into contact with gas molecules in the air, the properties of the materials may be changed. For example, when the graphene material comes into contact with the gas molecules in the air, the properties of the material may be changed after tens to hundreds seconds. When the black phosphorus material comes into contact with the gas molecules in the air, the material may be oxidized to be changed in terms of the properties thereof after ones minutes, and the degree of change is very high compared to the graphene material or another 2-dimensional material.

That is, the black phosphorus material may more strongly react with the gas molecules in the air, compared to the graphene material, and accordingly, the degree of change in properties of the black phosphorus material may be large.

The change in properties of the first active layer 130 including the black phosphorus material may be measured using the first electrode 150 and the second electrode 160 which are in contact with the upper side of the first active layer 130. The change in properties of the second active layer 140 including the graphene material may be measured using the third electrode 170 and the fourth electrode 180 which are in contact with the upper side of the second active layer 140.

Further, when the junction unit, at which the first active layer 130 partially undergoes heterojunction with the second active layer 140, comes into contact with the gas molecules in the air, the properties of the junction unit may be changed. A reduction in properties of the junction unit may be measured using the second electrode 160 and the third electrode 170 which are spaced apart from the junction unit by a predetermined distance.

The second active layer 140 including the graphene material may function to rapidly sense a gas leak in the chamber to thus improve the reaction sensitivity of the gas sensor 100. The first active layer 130 including the black phosphorus material may function to impart a large signal change over a long period of time to thus continuously sense a gas leak in the chamber even after there is no signal change and the second active layer 140 does not serve as a channel any longer due to saturation of the conductivity of the second active layer 140. Further, the junction unit, at which the first active layer 130 partially undergoes heterojunction with the second active layer 140, may impart a current change according to a difference in properties of the materials of the first active layer 130 and the second active layer 140 to thus rapidly sense a gas leak in the chamber, thereby improving the reaction sensitivity.

As described above, the gas sensor 100 according to the embodiment of the present disclosure may include the first and second active layers 130 and 140 including different materials to rapidly sense a gas leak, thereby improving the reaction sensitivity. Further, the gas sensor 100 according to the embodiment of the present disclosure may stably sense a gas leak in the air over a long period of time.

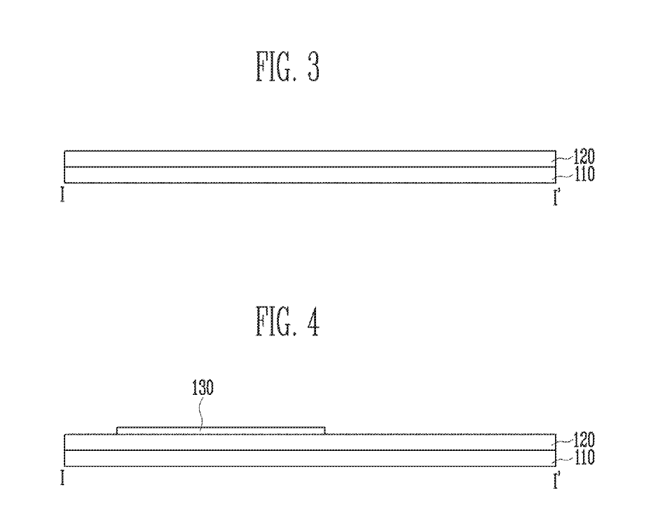

FIGS. 3 to 6 are sectional views sequentially showing manufacturing of the gas sensor of FIG. 2. A method of manufacturing a gas sensor according to a first embodiment of the present disclosure will be described with reference to FIGS. 3 to 6.

Referring to FIG. 3, the insulating layer 120 is formed on the substrate 110.

Examples of the substrate 110 may include a transparent inorganic base board, which includes glass, quartz, AlO, SiC, or MgO, a transparent flexible organic base board, which includes polyethylene terephthalate (PET), polystyrene (PS), polyimide (PI), polyvinyl chloride (PVC), polyvinylpyrrolidone (PVP), or polyethylene (PE), or a base board, which includes Si, Ge, GaAs, InP, InSb, InAs, AlAs, AlSb, CdTe, ZnTe, ZnS, CdSe, CdSb, or GaP, but are not limited thereto.

The insulating layer 120 may include a material, such as silicon nitrides (SiNx), silicon oxides (SiO2), BCB (benzocyclobutene), and other porous silica thin films, and may function to protect the surface of the substrate 110. The type and the thickness of the insulating layer 120 may determined in consideration of etch rates of photosensitive layers used during a process.

Referring to FIG. 4, the first active layer 130 is formed on the insulating layer 120.

The first active layer 130 may be a layer in which a black phosphor material having a 2-dimensional combination structure of black phosphorus (P) is deposited in a thin film form, and may be formed on the insulating layer 120 to have a predetermined area.

A process of manufacturing the black phosphorus material may be as follows, without being limited thereto.

The black phosphorus material may be exfoliated from black phosphorus crystals using a physical method (mechanical exfoliation and tapping method).

The black phosphorus material is known as the most stable material among allotropes of phosphorus, and the crystal structure of the black phosphorus material may have a structure including a layer in which one atom is bonded to three atoms like graphite. The black phosphorus material has the high mobility and band gap, and also has a semiconductor characteristic in which the state of the black phosphorus material is rapidly converted between insulation and conduction states.

In the case that the black phosphorus material is 3 nm or less in thickness, the black phosphorus material may be oxidized within ones minutes when exposed to the air. Further, in the case that the black phosphorus material is 9 nm or more in thickness, only the surface of the black phosphorus material may be oxidized when the black phosphorus material is exposed to the air. That is, the degree of oxidation of the black phosphorus material may depend on the thickness of the black phosphorus material.

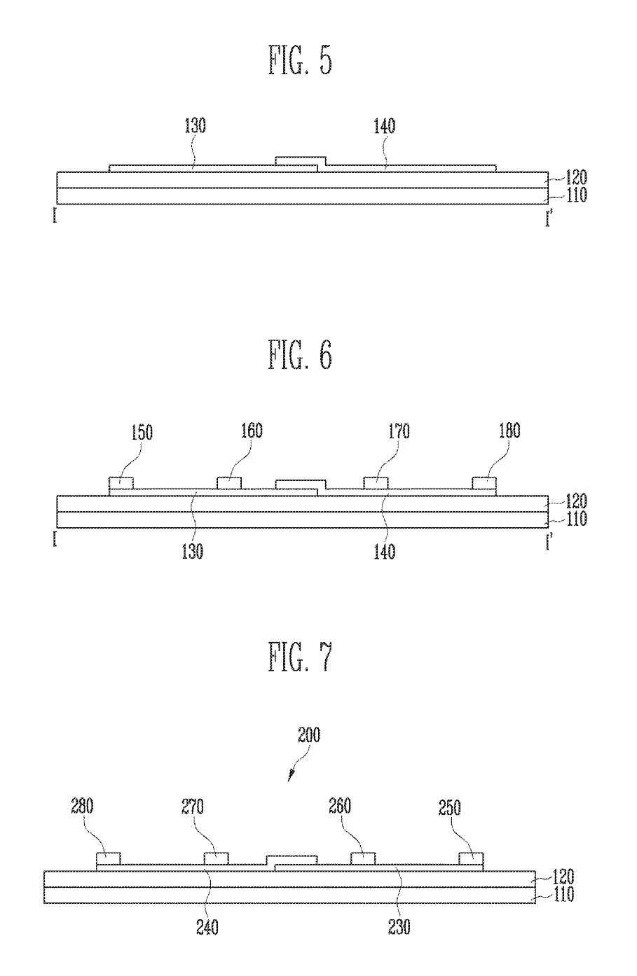

Subsequently, referring to FIG. 5, the second active layer 140, which undergoes heterojunction with a portion of the first active layer 130, is formed on the insulating layer 120.

The second active layer 140 is a layer in which a graphene material having a 2-dimensional planar combination structure is deposited in a thin film form, and is formed on the insulating layer 120 to have a predetermined area. The graphene material is a material that is structurally and chemically very stable, and a light absorption property, conversion efficiency of light into heat, and a heat transfer property are excellent in the material.

The graphene material, which is obtained using chemical vapor deposition (CVD), may be transferred and then patterned to form the second active layer 140. Further, the thin film of the graphene material may be obtained from graphite using chemical exfoliation to thus form the second active layer 140. In addition, graphene oxides in an aqueous solution state may be applied using spin coating on the insulating layer 120 to form the second active layer 140, without being limited thereto.

Referring to FIG. 6, the first electrode 150 and the second electrode 160, which are spaced apart from each other at a predetermined interval, are formed on the first active layer 130. In addition, the third electrode 170 and the fourth electrode 180, which are spaced apart from each other at a predetermined interval, are formed on the second active layer 140.

The first electrode 150 and the second electrode 160 may include any metal materials to allow a current to flow through the first active layer 130. For example, the first electrode 150 and the second electrode 160 may include any one selected from the group consisting of gold (Au), aluminum (Al), silver (Ag), beryllium (Be), bismuth (Bi), cobalt (Co), copper (Cu), chromium (Cr), hafnium (Hf), indium (In), manganese (Mn), molybdenum (Mo), magnesium (Mg), nickel (Ni), niobium (Nb), lead (Pb), palladium (Pd), platinum (Pt), rhodium (Rh), rhenium (Re), ruthenium (Ru), antimony (Sb), tantalum (Ta), tellurium (Te), titanium (Ti), vanadium (V), tungsten (W), zirconium (Zr), zinc (Zn), and combinations thereof, but are not limited thereto.

The third electrode 170 and the fourth electrode 180 may include any metal materials to allow a current to flow through the second active layer 140, and may include the same material as the first and second electrodes 150 and 160.

The first and second electrodes 150 and 160 and the third and fourth electrodes 170 and 180 may be formed using an E-beam lithography or thermal lithography process, without being limited thereto.

The first electrode 150 and the second electrode 160 may be in contact with the first active layer 130 and sense a change in current of the first active layer 130. The third electrode 170 and the fourth electrode 180 may be in contact with the second active layer 140 and sense a change in current of the second active layer 140. The second electrode 160 and the third electrode 170 may be spaced apart from the junction unit, at which the first active layer 130 undergoes heterojunction with the second active layer 140, by a predetermined distance, and may sense a change in current of the junction unit.

Based on the aforementioned manufacturing method, the gas sensor 100 according to the embodiment of the present disclosure may rapidly sense a gas leak and ensure the high reaction sensitivity over a long period of time using a change in properties of the first active layer 130 and the second active layer 140 including the different materials.

FIG. 7 is a sectional view of a gas sensor according to another embodiment of the present disclosure. In order to avoid the overlapping descriptions of the same parts, parts that are different from those of the gas sensor according to the aforementioned embodiment will be mainly described in the gas sensor according to another embodiment of the present disclosure. The constitutions of another embodiment of the present disclosure are considered to be the same as those of the gas sensor according to the aforementioned embodiment, unless otherwise described, and the same and similar reference numerals refer to the same and similar parts throughout.

Referring to FIG. 7, a gas sensor 200 according to another embodiment of the present disclosure may include a substrate 110, an insulating layer 120, a first active layer 230, a second active layer 240, a first electrode 250, a second electrode 260, a third electrode 270, and a fourth electrode 280.

The substrate 110 is a base board used as a semiconductor element, and examples of the base board may include a transparent inorganic base board, which includes silicon, glass, or quartz, but are not limited thereto. Examples of the substrate 110 may include a transparent flexible organic base board, which includes polyethylene terephthalate (PET), polystyrene (PS), polyimide (PI), polyvinyl chloride (PVC), polyvinylpyrrolidone (PVP), or polyethylene (PE), or Si, Ge, GaAs, InP, InSb, InAs, AlAs, AlSb, CdTe, ZnTe, ZnS, CdSe, CdSb, or GaP.

The insulating layer 120 may be disposed on the substrate 110 and may include a monolayer or a multilayer. The insulating layer 120 may include a material, such as silicon nitrides (SiNx), silicon oxides (SiO2), BCB (benzocyclobutene), and other porous silica thin films, and may function to protect the surface of the substrate 110. The type and the thickness of the insulating layer 120 may determined in consideration of etch rates of photosensitive layers used during a process. The first active layer 230 may be disposed on the insulating layer 120.

The first active layer 230 may be positioned on the right of the insulating layer 120 on the basis of a planar view, and may undergo heterojunction with a portion of the second active layer 240. The first active layer 230 may include a layer in which a graphene material having a 2-dimensional planar combination structure is deposited in a thin film form. The first active layer 230 may have a predetermined area, an atomic layer thickness, and a width of ones nm on the insulating layer 120.

The first active layer 230 may include a monolayer, a double layer, or a multilayer, and may directly grow on the insulating layer 120, without being limited thereto. The first active layer 230 may be used as a current path between the first electrode 250 and the second electrode 260, that is, a first channel region.

The second active layer 240 may be disposed on the insulating layer 120 and positioned on the left of the insulating layer 120 on the basis of a planar view, and may undergo heterojunction with a portion of the first active layer 230. The second active layer 240 may include a layer in which a black phosphorus material having a 2-dimensional combination structure of black phosphorus (P) is deposited in a thin film form. The second active layer 240 may have a predetermined area, an atomic layer thickness, and a width of ones μm on the insulating layer 120.

The second active layer 240 may be used as a current path between the third electrode 270 and the fourth electrode 280, that is, a second channel region.

A junction unit, at which the first active layer 230 undergoes heterojunction with the second active layer 240, may be used as a current path between the second electrode 260 and the third electrode 270, that is, a third channel region.

The first active layer 230 and the second active layer 240 may be disposed on the same line on the insulating layer 120 on the basis of a planar view. The first active layer 230 and the second active layer 240 may serve as the gas sensing layer of the gas sensor 200 due to properties of the materials (graphene and black phosphorus) constituting the layers.

The first electrode 250 and the second electrode 260 may be disposed on the first active layer 230 and spaced apart from each other at a predetermined interval. The first electrode 250 and the second electrode 260 may include any metal materials having the conductivity to allow a current to flow through the first active layer 230. A change in current of the first active layer 230 may be sensed using the first electrode 250 and the second electrode 260.

The third electrode 270 and the fourth electrode 280 may be disposed on the second active layer 240 and spaced apart from each other at a predetermined interval. The third electrode 270 and the fourth electrode 280 may include the same materials as the first and second electrodes 250 and 260. A change in current of the second active layer 240 may be sensed using the third electrode 270 and the fourth electrode 280. The second electrode 260 and the third electrode 270 may be spaced apart from the junction unit, at which the first active layer 230 undergoes heterojunction with the second active layer 240, by a predetermined distance. A change in current of the junction unit may be sensed using the second electrode 260 and the third electrode 270.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A gas sensor comprising:
a substrate;
an insulating layer disposed on the substrate;
a first active layer disposed on the insulating layer;
a second active layer which is disposed on the insulating layer and undergoes heterojunction with a portion of the first active layer;
a first electrode and a second electrode which are disposed on the first active layer and are spaced apart from each other at a predetermined interval; and
a third electrode and a fourth electrode which are disposed on the second active layer and are spaced apart from each other at a predetermined interval,
wherein the first active layer and the second active layer include different materials.

2. The gas sensor according to claim 1, wherein the first active layer includes a black phosphorus material.

3. The gas sensor according to claim 1, wherein the second active layer includes a graphene material.

4. The gas sensor according to claim 1, wherein the second active layer includes a transition metal dichalcogenide material.

5. The gas sensor according to claim 1, wherein the first active layer and the second active layer are positioned on a same line on a basis of a planar view.

6. The gas sensor according to claim 1, wherein the first electrode and the second electrode are in contact with the first active layer and are configured to sense a change in current of the first active layer.

7. The gas sensor according to claim 1, wherein the third electrode and the fourth electrode are in contact with the second active layer and are configured to sense a change in current of the second active layer.

8. The gas sensor according to claim 1, wherein the second electrode and the third electrode are spaced apart from a junction unit, at which the first active layer and the second active layer are in contact with each other, by a predetermined distance, and are configured to sense a change in current of the junction unit.

9. The gas sensor according to claim 1, wherein the first to fourth electrodes include any one selected from the group consisting of gold (Au), aluminum (Al), silver (Ag), beryllium (Be), bismuth (Bi), cobalt (Co), copper (Cu), chromium (Cr), hafnium (Hf), indium (In), manganese (Mn), molybdenum (Mo), magnesium (Mg), nickel (Ni), niobium (Nb), lead (Pb), palladium (Pd), platinum (Pt), rhodium (Rh), rhenium (Re), ruthenium (Ru), antimony (Sb), tantalum (Ta), tellurium (Te), titanium (Ti), vanadium (V), tungsten (W), zirconium (Zr), zinc (Zn), and combinations thereof.

10. A method of manufacturing a gas sensor, the method comprising:
forming an insulating layer on a substrate;
forming a first active layer on the insulating layer;
forming a second active layer, which undergoes heterojunction with a portion of the first active layer, on the insulating layer; and
forming a first electrode and a second electrode, which are spaced apart from each other at a predetermined interval, on the first active layer, and forming a third electrode and a fourth electrode, which are spaced apart from each other at a predetermined interval, on the second active layer,
wherein the first active layer and the second active layer include different materials.

11. The method according to claim 10, wherein the first active layer includes a black phosphorus material, and the second active layer includes any one of a graphene material and a transition metal dichalcogenide material.

12. The method according to claim 10, wherein the second active layer is formed on the insulating layer using chemical vapor deposition (CVD).

13. The method according to claim 10, wherein the first active layer includes any one of a graphene material and a transition metal dichalcogenide material, and the second active layer includes a black phosphorus material.

14. The method according to claim 10, wherein the first active layer and the second active layer are positioned on a same line on a basis of a planar view.

15. The method according to claim 10, wherein the first to fourth electrodes include any one selected from the group consisting of gold (Au), aluminum (Al), silver (Ag), beryllium (Be), bismuth (Bi), cobalt (Co), copper (Cu), chromium (Cr), hafnium (Hf), indium (In), manganese (Mn), molybdenum (Mo), magnesium (Mg), nickel (Ni), niobium (Nb), lead (Pb), palladium (Pd), platinum (Pt), rhodium (Rh), rhenium (Re), ruthenium (Ru), antimony (Sb), tantalum (Ta), tellurium (Te), titanium (Ti), vanadium (V), tungsten (W), zirconium (Zr), zinc (Zn), and combinations thereof.
